(19) United States
(12) Patent Application Publication
(10) Pub. No.: US 2013/0093101 A1
(43) Pub. Date: Apr. 18, 2013

(54) SEMICONDUCTOR DEVICE

(71) Applicants: Masateru Saigusa, Chiba (JP); Masamitsu Oshikiri, Kanagawa (JP)

(72) Inventors: Masateru Saigusa, Chiba (JP); Masamitsu Oshikiri, Kanagawa (JP)

(73) Assignee: Kabushiki Kaisha Toshiba, Tokyo (JP)

(21) Appl. No.: 13/427,293

(22) Filed: Mar. 22, 2012

(30) Foreign Application Priority Data
Oct. 17, 2011 (JP) 2011-227560

(51) Int. Cl. H01L 23/48

(52) U.S. Cl. 257/777; 257/782; 257/E23.01

(57) ABSTRACT

According to one embodiment, a semiconductor device is provided. The semiconductor device includes a package substrate; a first semiconductor chip mounted on the package substrate and adapted to include a plurality of first bonding pads arranged in a first order on an upper surface; a second semiconductor chip arranged on the first semiconductor chip and adapted to include a plurality of second bonding pads arranged in the first order on an upper surface; and first bonding wires configured to connect each of the plurality of first bonding pads and the plurality of second bonding pads.

### CROSS-REFERENCE TO RELATED APPLICATIONS

This application is based upon and claims the benefit of priority from Japanese Patent Application No. 2011-227560, filed on Oct. 17, 2011; the entire contents of which are incorporated herein by reference.

### FIELD

Embodiments described herein relate generally to a semiconductor device.

### BACKGROUND

In a semiconductor device mounted with a memory chip and a logic IC (controller chip) for memory control, the chip size is becoming larger with increase of a capacity of the memory chip. In the controller chip for controlling the memory chip, on the other hand, the chip size is becoming smaller to reduce the manufacturing cost, and thus the bonding pitch is also becoming narrower.

In the conventional semiconductor device, the memory chip mounted on a package substrate and the controller mounted on the memory chip are connected by way of the package substrate, and thus the wiring pattern in the package substrate is complicating, the arrangement of the bonding wire is very complex, and the manufacturing is difficult. Furthermore, the wiring pattern length in the package substrate becomes long, which may inhibit higher speed in reading and writing data with respect to the memory chip by the controller chip.

### BRIEF DESCRIPTION OF THE DRAWINGS

FIG. 1A is a plan view schematically showing a configuration of a semiconductor device according to a first embodiment;

FIG. 1B is a side view schematically showing the configuration of the semiconductor device according to the first embodiment;

FIG. 1C is a plan view schematically showing a variant of FIG. 1A;

FIG. 1D is a plan view schematically showing a variant of FIG. 1A;

FIG. 1E is a plan view schematically showing a variant of FIG. 1A;

FIG. 2A is a plan view schematically showing a configuration of a conventional semiconductor device;

FIG. 2B is a side view schematically showing the configuration of the conventional semiconductor device;

FIG. 3A is a plan view showing an example of a configuration of a semiconductor device in which four memories are connected to one controller;

FIG. 3B is a side view showing an example of the configuration of the semiconductor device in which four memories are connected to one controller;

FIG. 4A is a plan view showing an example of a configuration of a semiconductor device in which the bonding pad for the memory chip and the bonding pad for the host are arranged in a mixed manner on one side of the controller;

FIG. 4B is a side view showing an example of the configuration of the semiconductor device in which the bonding pad for the memory chip and the bonding pad for the host are arranged in a mixed manner on one side of the controller;

FIG. 5A is a plan view schematically showing a configuration of a semiconductor device according to a second embodiment;

FIG. 5B is a side view schematically showing the configuration of the semiconductor device according to the second embodiment;

FIG. 6A is a plan view schematically showing a configuration of a semiconductor device according to a third embodiment; and

FIG. 6B is a side view schematically showing the configuration of the semiconductor device according to the third embodiment.

### DETAILED DESCRIPTION

In general, according to one embodiment, a semiconductor device is provided. The semiconductor device includes a package substrate, a first semiconductor chip mounted on the package substrate and provided with a plurality of first bonding pads, individually assigned with a function and arranged in a first order, on an upper surface, a second semiconductor chip with an outer shape smaller than the first semiconductor chip arranged on the first semiconductor chip and provided with a plurality of second bonding pads, assigned with a function corresponding to each of the plurality of first bonding pads and arranged to be lined in the first order, on an upper surface, and a first bonding wires for connecting each of the plurality of first bonding pads and each of the plurality of second bonding pads.

Exemplary embodiments of semiconductor device will be explained below in detail with reference to the accompanying drawings. The present invention is not limited to the following embodiments.

### First Embodiment

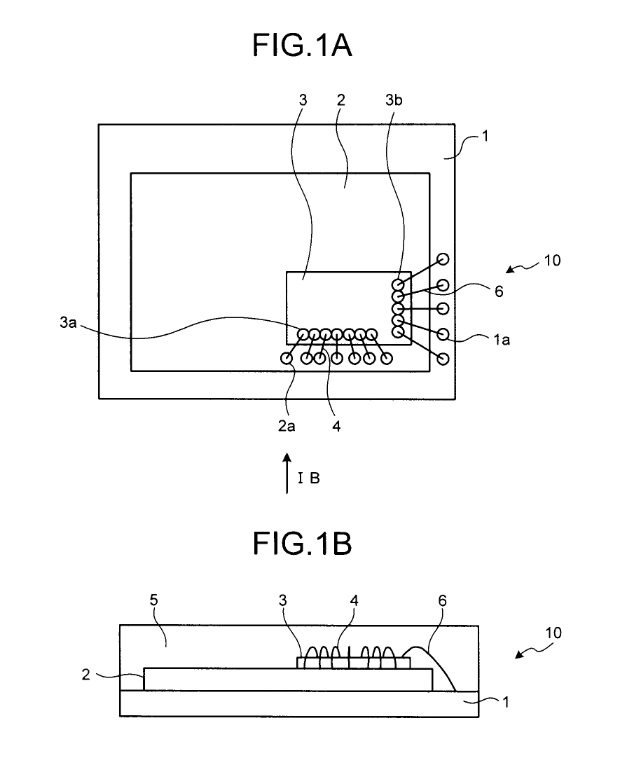

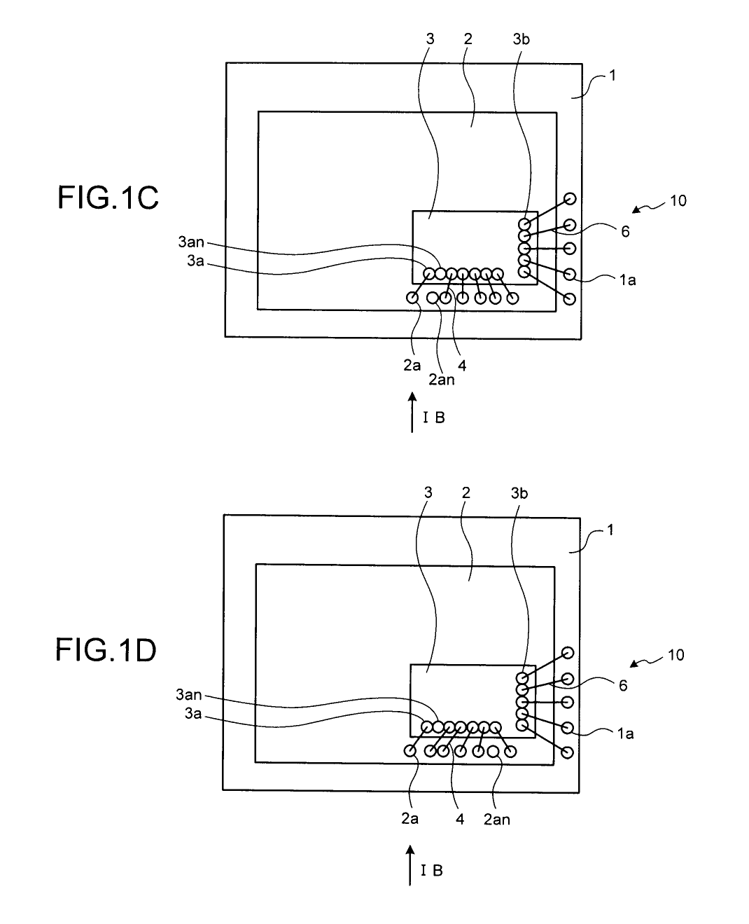

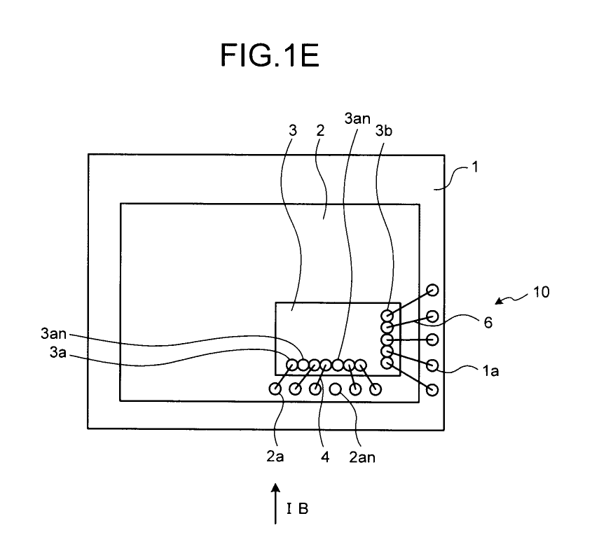

FIG. 1A and FIG. 1B are diagrams schematically showing a configuration of a semiconductor device according to a first embodiment, where FIG. 1A is a plan view and FIG. 1B is a side view seen from a direction of an arrow 1B in FIG. 1A. A semiconductor device 10 includes a memory chip (semiconductor memory chip; hereafter called “memory”) 2 as a first semiconductor chip mounted on a package substrate 1, and a controller chip 3 (hereafter called “controller”) as a second semiconductor chip mounted in an overlapping manner on the memory 2 and adapted to control the memory 2, where the memory 2 and the controller 3 are resin sealed with a sealing resin 5. The controller 3 has a smaller outer shape dimension than the memory 2, and is arranged at a portion at the corner of the memory 2. The controller 3 may be arranged at a portion other than the corner of the memory 2.

The memory 2 and the controller 3 are directly connected through first bonding wires 4. The first bonding wires 4 are bridged between bonding pads 2a as first bonding pads arranged on an upper surface of the memory 2, and bonding pads 3a as second bonding pads arranged on an upper surface of the controller 3. Each of the bonding pads 2a is individually assigned with a function of power supply, ground, clock, data, various types of signals, and the like, and the pad of each function arranged in an order (first order). Each of the bonding pads 3a is assigned with a function corresponding to the respective bonding pads 2a, and arranged such that the pad of the function corresponding to the bonding pads 2a is lined in the same order (lined in first order).

The pitch of the bonding pads 3a is wider than the pitch of the bonding pads 2a, and the first bonding wires 4 bridged between the bonding pads 2a, 3a positioned at the ends of the rows are arranged in a tilted with respect to a direction orthogonal to an arranging direction of the bonding pads 2a. When an angle with respect to a direction orthogonal to the arranging direction of the bonding pads 2a of the memory 2 becomes large, breaking of wire easily occurs when resin sealing with the sealing resin 5. Thus the first bonding wires 4 are formed such that the relevant angle is smaller than or equal to an angle. By way of example, each of the first bonding wires 4 has an angle with respect to the direction orthogonal to the arranging direction of the bonding pads 2a of the memory 2 of smaller than or equal to 40°.

The breaking of wire at the time of resin sealing with the sealing resin 5 easily occurs in case of the wire length of the first bonding wires 4 become long. Thus the breaking of wire is less likely to occur in case the wire length of the first bonding wires 4 are smaller than or equal to a predetermined length. If a distance between the row of the bonding pads 2a and the row of the bonding pads 3a is short, the angle with respect to the direction orthogonal to the arranging direction of the bonding pads 2a of the first bonding wires 4 bridged between the bonding pads 2a, 3a positioned at the ends of the rows becomes large. Thus, the bonding pads 2a, 3a are arranged so that the row of the bonding pads 2a and the row of the bonding pads 3a are spaced apart by an extent to suppress the occurrence of breaking of wire. By way of example, the occurrence of breaking of wire can be effectively suppressed by having the wire length of the first bonding wires 4 between 0.5 mm and 2 mm, and the angle of the first bonding wires 4 with respect to the direction orthogonal to the arranging direction of the bonding pads 2a of the memory 2 smaller than or equal to 40°.

Furthermore, the controller 3 is also connected to the package substrate 1 through second bonding wires 6. The second bonding wires 6 are bridged between the bonding pads la as fourth bonding pads arranged on an upper surface of the package substrate 1, and bonding pads 3b as third bonding pads arranged separate from the bonding pads 3a on the upper surface of the controller 3. The lengths of the second bonding wires 6 are suppressed short since the controller 3 is arranged at a portion at the corner of the memory 2. The package substrate 1 is formed with a wiring (not shown) extending from the bonding pads la towards an external device (not shown).

The order of the functions of the bonding pads 2a at the upper surface of the memory 2 and the order of the functions of the bonding pads 3a at the upper surface of the controller 3 are coincided. In other words, in the present embodiment, the wiring pattern for aligning the order of the functions of the bonding pads 2a, 3a with the memory 2 and the controller 3 is formed inside the memory 2 and the controller 3. Thus, the order of the functions does not need to change with the wiring pattern in the package substrate 1, so that the memory 2 and the controller 3 can be directly connected with the first bonding wires 4.

As shown in FIG. 1C, the bonding pads 2an, 3an not connected with the bonding wire may exist as long as the order of the functions is not changed. As shown in FIG. 1D, the position from the left side in the figure of the bonding pad 2an not connected with the bonding wire and the bonding pad 3an not connected with the bonding wire may differ as long as the order of the functions is not changed. As shown in FIG. 1E, the number of bonding pads 2an not connected with the bonding wire and the bonding pads 3an not connected with the bonding wire may differ as long as the order of the functions is not changed.

The order of the functions of the bonding pads 3b at the upper surface of the controller 3 and the order of the functions of the bonding pads la arranged at the upper surface of the package substrate 1 may be coincided.

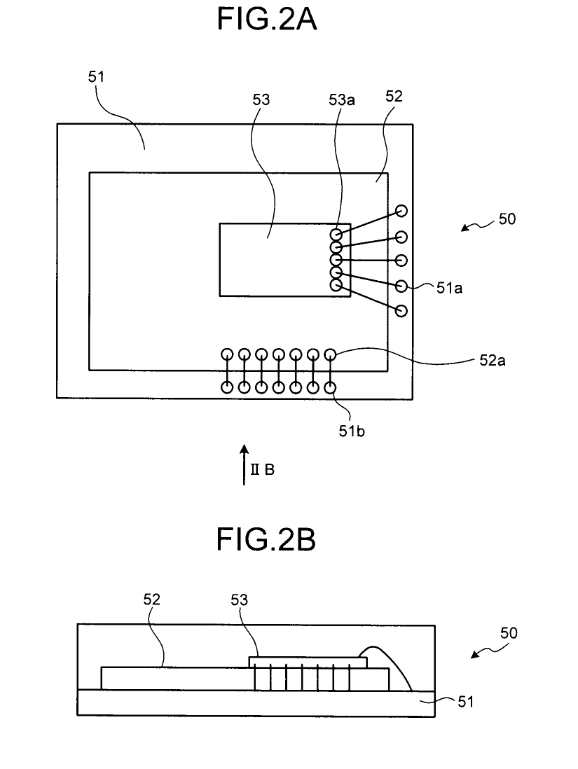

FIG. 2A and FIG. 2B are drawings schematically showing the configuration of a conventional semiconductor device, where FIG. 2A is a plan view and FIG. 2B is a side view seen from a direction of an arrow IIB in FIG. 2A. A conventional semiconductor device 50 combines an existing memory 52 and an existing controller 53, where the order of the functions of the bonding pad 52a arranged on the upper surface of the memory 52 and the order of the functions of the bonding pad 53a arranged on the upper surface of the controller 53 do not coincide. Thus, the wirings connecting the memory 52 and the controller 53 need to interpose a package substrate 51 and the like for intersect the other wirings connecting the memory 52 and the controller 53 at different grades. For instance, the connection between the memory 52 and the controller 53 is made by combining the boding wire bridged between the bonding pad 51a and the bonding pad 53a, the wiring pattern in the package substrate 51, and the bonding wire bridged between the bonding pad 52a of the memory 52 and the bonding pad 51b. In other words, the memory 52 and the controller 53 cannot be directly connected.

Consideration is made in arranging a re-wiring layer on the upper surface of the memory 52 to become the lower side, and electrically connecting the controller 53 to become the upper side and the package substrate 51 through the re-wiring layer. However, in a conventional technology in which the re-wiring layer is arranged on the upper surface of the memory 52 to become the lower side, the man-hour in the manufacturing steps increases as the re-wiring layer is formed on the memory 52 to become the lower side, and hence the manufacturing cost increases.

The semiconductor device 10 according to the present embodiment has the memory 2 and the controller 3 directly connected with the first bonding wires 4, and hence the wiring length between the memory 2 and the controller 3 can be shortened compared to when connecting them through the package substrate 1. By way of example, if the package substrate 1 is 18×14 mm, the memory 2 is 15×10 mm, and the controller 3 is 3×3 mm, the wiring length between the memory 2 and the controller 3 can be shortened by about 20 mm by adopting the structure of the present embodiment compared to when connecting the memory 2 and the controller 3 through the package substrate 1. The degradation of the signal between the memory 2 and the controller 3 can be suppressed and the speed of data exchange can be increased by shortening the wiring length between the memory 2 and the controller 3. Furthermore, as a special task is unnecessary at the time of assembly, manufacturing can be carried out using existing equipment, and thus the manufacturing cost does not increase.

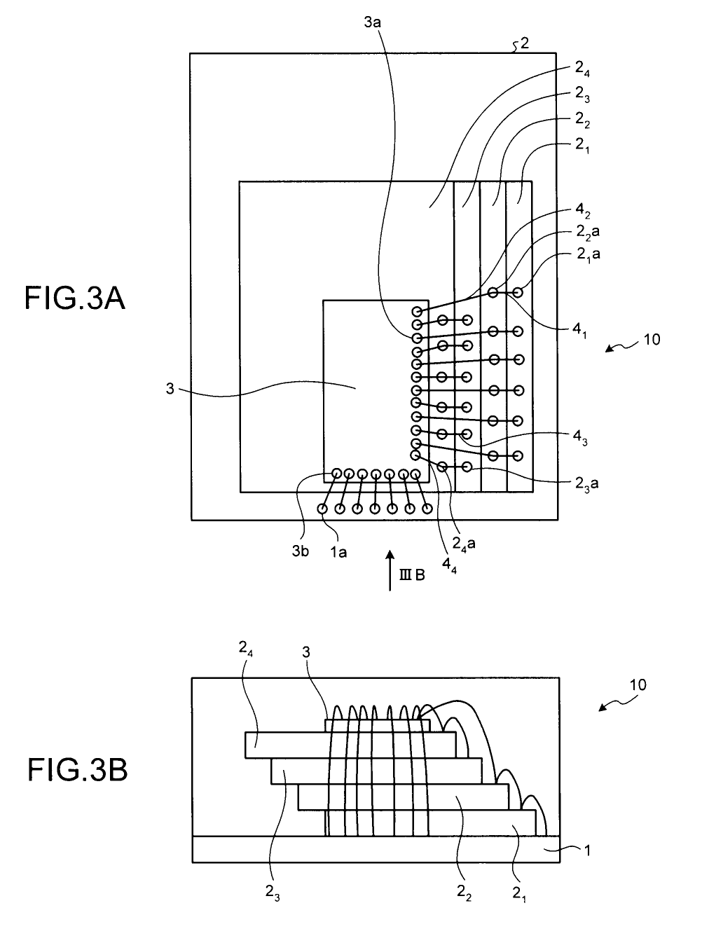

The configuration in which the memory and the controller is arranged one to one has been described by way of example, but a plurality of memories may be connected to one controller. FIG. 3A and FIG. 3B are diagrams showing an example of a configuration of a semiconductor device in which four memories are connected to one controller, where FIG. 3A is a plan view and FIG. 3B is a side view seen from a direction of an arrow IIIB in FIG. 3A. In the semiconductor device 10, the memories 2₁ to 2₄ are slightly shifted and overlapped, so that the memories 2₁ to 2₃ other than the one at the uppermost level also have one part of the upper surface exposed. Bonding pads 2₁a to 2₃a of the memories 2₁ to 2₃ are formed in a portion not covered by the memories 2₂ to 2₄ at the upper level. Therefore, the bonding pads 2₁a to 2₄a of each memory 2₁ to 2₄ and the bonding pad 3a of the controller 3 can be directly connected with first bonding wires 4₁ to 4₄. Larger capacity of the semiconductor device 10 can be realized as the controller 3 carries out read and write of data with respect to the plurality of memories 2₁ to 2₄.

If the memories 2₁ to 2₄ are the same type memory, the bonding pads 2₁a to 2₄a of the respective memories are lined in a line with respect to the controller 3. For instance, when controlling two sets of memories as one memory (e.g., when having memories 2₁ to 2₂, memories 2₃ to 2₄ as one set), the data pads of each set are interfered each other if four memories are arranged. Thus, the memories 2₃ to 2₄ are shifted so as to be orthogonal to the direction the bonding wires 4₁ to 4₄ are extended. As a result, the interference of the data pads of each set can be prevented, and connection can be easily made with the bonding wires 4. In this case, the memories 2₁ to 2₂, which is the set on the lower side, is preferably shifted in a direction opposite to the side on which the bonding pads 3b are arranged. As a result, the distance of the bonding pads 3b and the bonding pads 1a can be reduced. The order of the functions of the bonding pads 3a of the controller 3 is coincided with the order of the functions of the bonding pads 2₁a to 2₄a of the respective memories by continuously arranging two bonding pads having the same function. In other words, even if the bonding pads having the same function are continuously arranged, the orders of the functions are considered to be coincided as long as the bonding wires do not interfere.

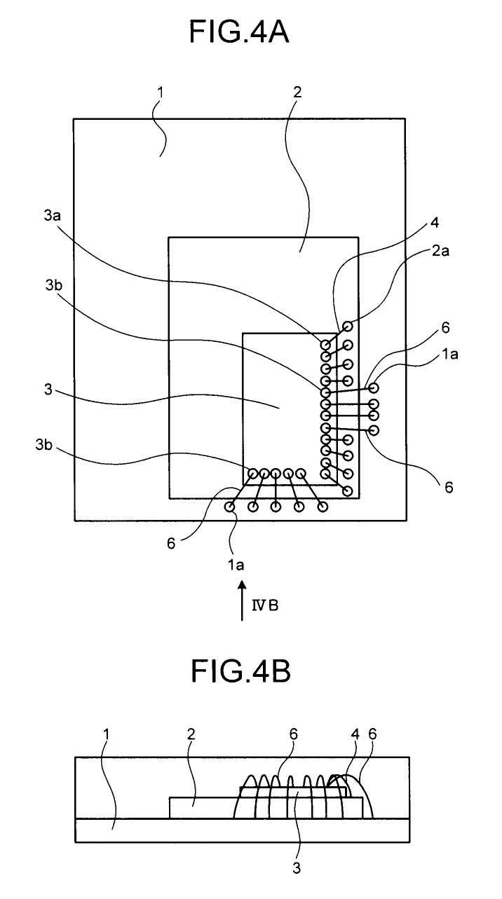

The configuration in which the bonding pads for connecting the memory are arranged on one side of the controller and the bonding pads for connecting the host are arranged on the other side has been described by way of example, but the bonding pads for connecting the memory and the bonding pads for connecting the host may be arranged in a mixed manner on one side of the controller. FIG. 4A and FIG. 4B are diagrams showing an example of a configuration of a semiconductor device in which the bonding pad for the memory and the bonding pad for the host are arranged in a mixed manner on one side of the controller, where FIG. 4A is a plan view and FIG. 4B is a side view seen from a direction of an arrow IVB in FIG. 4A. The bonding pads 3a for connection with the memory 2 are arranged on one side sandwiching a corner of the controller 3 adjacent to the corner of the memory 2, and the bonding pads 3a and the bonding pad 3b are arranged on the other side sandwiching the corner of the controller 3 adjacent to the corner of the memory 2. Therefore, the first bonding wires 4 is formed along one side sandwiching the corner of the controller 3 adjacent to the corner of the memory 2, and the second bonding wires 6 is formed along the one side of the controller 3 and the other side sandwiching the corner of the controller 3 adjacent to the corner of the memory 2. Thus, even if the number of second bonding wires 6 is greater than the number of first bonding wires 4, the first bonding wire 4 and the second bonding wires 6 can be arranged without bias.

Therefore, the memory and the controller can be directly connected without intersecting the first bonding wire by designing both the memory and the controller assuming the state assembled as the semiconductor device and coinciding the orders of the bonding pads.

### Second Embodiment

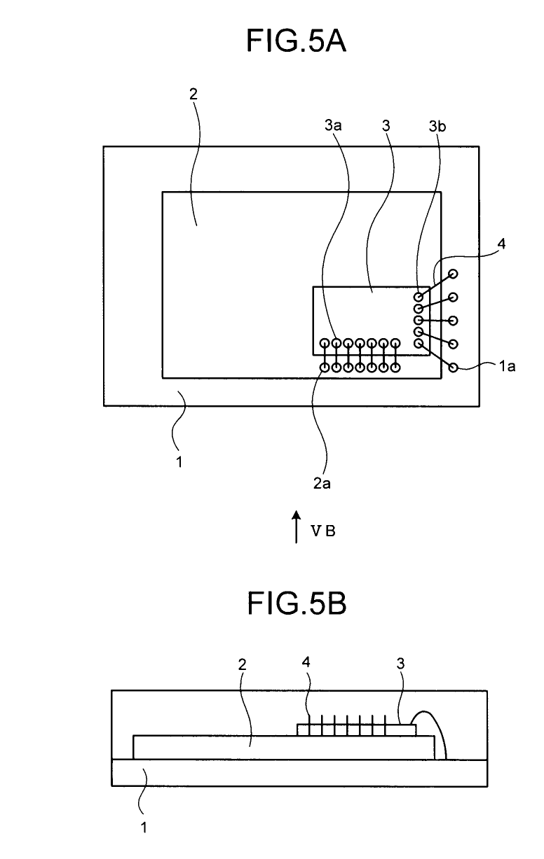

FIG. 5A and FIG. 5B are diagrams schematically showing a configuration of a semiconductor device according to a second embodiment, where FIG. 5A is a plan view and FIG. 5B is a side view seen from a direction of an arrow VB in FIG. 5A. In the present embodiment, the bonding pads 2a at the upper surface of the memory 2 mounted on the package substrate 1 and the bonding pads 3a at the upper surface of the controller 3 are arranged at the same interval (pitch). Other portions are similar to the first embodiment. The length of all the first bonding wires 4 connecting the memory 2 and the controller 3 can be aligned short by arranging the bonding pads 2a and the bonding pads 3a at the same interval.

In the present embodiment, all the first bonding wires 4 are arranged parallel to the direction orthogonal to the arranging direction of the bonding pads 2a. Thus an angle with respect to the direction orthogonal to the arranging direction of the bonding pads 2a of the first bonding wire 4s bridged between the bonding pads 2a, 3a positioned at the ends of the rows does not become large even if the distance between the row of the bonding pads 2a and the row of the bonding pads 3a is made small. Therefore, the lengths of the first bonding wires 4 can be made shorter than in the first embodiment.

### Third Embodiment

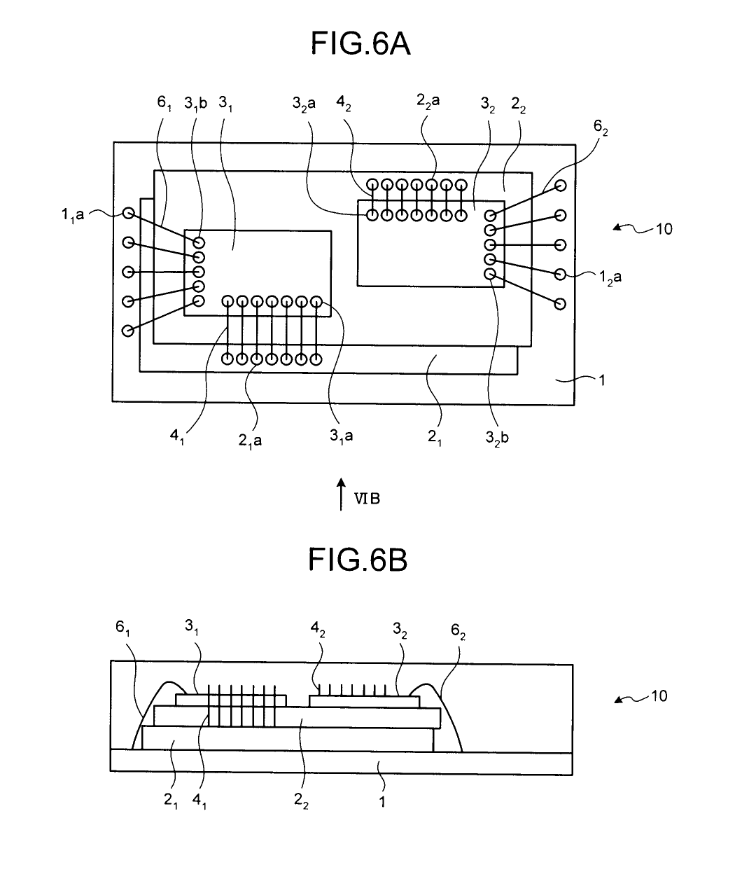

FIG. 6A and FIG. 6B are diagrams schematically showing a configuration of a semiconductor device according to a third embodiment, where FIG. 6A is a plan view and FIG. 6B is a side view seen from the direction of an arrow VIB in FIG. 6A. In the present embodiment, the semiconductor device 10 includes memories 2₁, 2₂ and controllers 3₁, 3₂. The memories 2₁, 2₂ are arranged in a shifted manner on the package substrate 1, and the controllers 3₁, 3₂ are mounted lined on the memory 2₂ of the upper level. The bonding pad 2₁a of the memory 2₁ of the lower level is arranged at a portion not covered by the memory 2₂ of the upper level. The controller 3₁ is wire bonded to the memory 2₁ of the lower level and the package substrate 1 by the first bonding wires 4₁ and the second bonding wires 6₁, respectively. In other words, the bonding wires 4₁ are bridged between the bonding pads 2₁a arranged at the upper surface of the memory 2₁ and the bonding pads 3₁a arranged at the upper surface of the controller 3. Similarly, the bonding wires 6₁ are bridged between the bonding pads 1₁a arranged at the upper surface of the package substrate 1 and the bonding pads 3₁b arranged at the upper surface of the controller 3. The controller 3₂ is bonded to the memory 2₂ of the upper level and the package substrate 1 by the first bonding wires 4₂ and the second bonding wires 6₂, respectively. In other words, the bonding wires 4₂ are bridged between the bonding pads 2₂a arranged at the upper surface of the memory 2₂ and the bonding pads 3₂a arranged at the upper surface of the controller 3. Similarly, the bonding wires 6₂ are bridged between the bonding pads 1₂a arranged at the upper surface of the package substrate 1 and the bonding pads 3₂b arranged at the upper surface of the controller 3.

In the present embodiment, the read and write of data with respect to the memory 2₁ of the lower level are controlled by the controller 3₁, and the read and write of data with respect to the memory 2₂ of the upper level are controlled by the controller 3₂, and thus the read and write of data with respect to the respective memory 2₁, 2₂ can be carried out in parallel. Thus, the speed of read and write of the data with respect to the entire semiconductor device 10 can be enhanced.

The memory 2₁ and the memory 2₂ may be the same type memory, and the memory 2₂ of the upper level may be arranged by being rotated 180 degrees. Similarly, the controller 3₁ and the controller 3₂ may be the same type controller, and may be arranged by being rotated 180 degrees. In other words, a set of the memory 2₁ and the controller 3₁, and a set of the memory 2₂ and the controller 3₂ are arranged in an overlapping manner. The controllers 3₁, 3₂ may be arranged at the opposing corners of the four sides of the memory 2₂ of the upper level, and the memory 2₁ and the memory 2₂ may be arranged by being rotated 180 degrees, so that the memory 2₁ and the memory 2₂, as well as the controller 3₁ and the controller 3₂ can be arranged without increasing the area seen from up above.

A configuration of including two controllers has been described by way of example, but three or more sets of controller and memory may be arranged. Furthermore, at least one of each controller may control the read and write of data to a plurality of memories, as described in the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a package substrate;
a first semiconductor chip mounted on the package substrate and included a plurality of first bonding pads individually assigned with a function and arranged in a first order on an upper surface;
a second semiconductor chip, which outer shape is smaller than the first semiconductor chip, arranged on the first semiconductor chip and included a plurality of second bonding pads assigned with a function corresponding to each of the plurality of first bonding pads and arranged to line in the first order on an upper surface; and
first bonding wires configured to connect each of the plurality of first bonding pads and the plurality of second bonding pads.

2. The semiconductor device according to claim 1, wherein a pitch of the first bonding pads and a pitch of the second bonding pads are the same.

3. The semiconductor device according to claim 2, wherein the second semiconductor chip is arranged at a corner of the first semiconductor chip.

4. The semiconductor device according to claim 3, further comprising:
a plurality of third bonding pads arranged on the upper surface of the second semiconductor chip;
a plurality of fourth bonding pads arranged on the package substrate; and
a second bonding wire configured to connect one of the plurality of third bonding pads and one of the plurality of fourth bonding pads; wherein
the first bonding wires are formed along one side sandwiching a corner adjacent to the corner of the first semiconductor chip of the second semiconductor chip; and
the second bonding wires are formed along the one side of the second semiconductor chip and another side adjacent to the one side and sandwiching the corner of the second semiconductor chip.

5. The semiconductor device according to claim 4, wherein the first bonding wires formed along the one side of the semiconductor chip are sandwiched by the second bonding wires.

6. The semiconductor device according to claim 4, wherein the third bonding pads are individually assigned with a function and arranged in a second order, and the fourth bonding pads are assigned with a function corresponding to each of the third bonding pads and arranged to line in the second order.

7. The semiconductor device according to claim 1, further comprising:
a plurality of sets of the first semiconductor chip and the second semiconductor chip;
a plurality of third bonding pads arranged on the upper surface of the second semiconductor chip;
a plurality of fourth bonding pads arranged on the package substrate; and
a second bonding wires configured to connect one of the plurality of third bonding pads and one of the plurality of fourth bonding pads; wherein
the first bonding wires are formed along one side sandwiching a corner adjacent to the corner of the first semiconductor chip of the second semiconductor chip; and
the second bonding wires are formed along another side adjacent to the one side of the second semiconductor chip.

8. The semiconductor device according to claim 7, wherein the plurality of first semiconductor chips includes the other one side, and are overlapped with the one side shifted.

9. The semiconductor device according to claim 8, wherein two of the first semiconductor chips form one set, the first semiconductor chips forming the one set are same type, the first bonding pads of the first semiconductor chips forming the one set are connected with third bonding wires, and the third bonding wires of the respective set of first semiconductor chips is shifted to be orthogonal to a direction the third bonding wires are extended.

10. The semiconductor device according to claim 9, wherein the first bonding pads are data pads.

11. The semiconductor device according to claim 9, wherein the bonding pads assigned the same function of the second bonding pads are continuously arranged.

12. The semiconductor device according to claim 7, wherein the third bonding pads are individually assigned with a function and arranged in a second order, and the fourth bonding pads are assigned with a function corresponding to each of the third bonding pads and arranged to line in the second order.

13. The semiconductor device according to claim 1, wherein two first semiconductor chips are provided, two second semiconductor chips are provided, the second semiconductor chips are mounted lined on the first semiconductor chip of an upper level, and the two second semiconductor chips are arranged at opposing corners of the first semiconductor chip.

14. The semiconductor device according to claim 13, wherein the first semiconductor chip is arranged by being rotated by 180 degrees and the second semiconductor chip is arranged by being rotated by 180 degrees.

15. The semiconductor device according to claim 1, wherein each of the first bonding wires arranged between the first bonding pads and the second bonding pads positioned at ends of rows has an angle with respect to a direction orthogonal to an arranging direction of the first bonding pads of the first semiconductor chip of smaller than or equal to 40°.

16. The semiconductor device according to claim 15, wherein the second semiconductor chip is arranged at a corner of the first semiconductor chip.

17. The semiconductor device according to claim 16, further comprising:
a plurality of third bonding pads arranged on an upper surface of the second semiconductor chip;
a plurality of fourth bonding pads arranged on the package substrate; and
second bonding wires configured to connect the third bonding pads and the fourth bonding pads; wherein
the first bonding wires are formed along one side sandwiching a corner adjacent to the corner of the first semiconductor chip of the second semiconductor chip; and
the second bonding wires are formed along the one side of the semiconductor chip and another side adjacent to the one side and sandwiching the corner of the second semiconductor chip.
